(19) United States
(12) Patent Application Publication
(10) Pub. No.: US 2006/0279363 A1
(43) Pub. Date: Dec. 14, 2006

(54) Pll circuit

(75) Inventor: Hideki Shirasu, Gunma (JP)

Correspondence Address: GREENBLUM & BERNSTEIN, P.L.C., 1950 ROLAND CLARKE PLACE, RESTON, VA, 20191, US

(73) Assignee: ADVANTEST CORPORATION, Tokyo (JP)

(21) Appl. No.: 10/555,181

(22) PCT Filed: Apr. 27, 2004
(86) PCT No.: PCT/JP04/06082

§ 371 Date: Jan. 17, 2006

(51) Int. Cl. H03L 7/00

(52) U.S. Cl. 331/16

(57) ABSTRACT

An arrangement is provided for reducing phase noise of a phase comparator in a PLL circuit. A voltage controlled oscillator (VCO) responsive to a voltage of an input signal controls a frequency of an output signal. An in-loop frequency divider frequency divides the output signal by two to output two output frequency divided signals. An in-loop phase shifter shifts the output frequency divided signals such that they are different in phase by 360 degrees/2 (e.g., 180 degrees). A reference frequency divider frequency divides a reference signal by two to output two reference frequency divided signals. A reference phase shifter shifts the reference frequency divided signals such that they are different in phase by 180 degrees. A plurality of phase comparators output signals in accordance with phase differences between the output frequency divided signals that are different in phase by 180 degrees and respective reference frequency divided signals that are different in phase by 180 degrees, and an adder sums outputs of the plurality of phase comparators. A low-pass filter passes therethrough and applies the low frequency components of the output of the adder to the voltage controlled oscillator.

### TECHNICAL FIELD

The present invention relates to a reduction of a noise in a phase comparator in a PLL (Phase Locked Loop) circuit.

### BACKGROUND ART

Conventionally, there has been used a PLL (Phase Locked Loop) circuit in a frequency multiplier and the like. The PLL circuit includes a reference oscillator and a phase comparator. Within a loop bandwidth of the PLL circuit, a phase noise of the reference oscillator and a phase noise of the phase comparator mainly cause a phase noise of the PLL circuit. An oscillator with a low phase noise such as a crystal oscillator is often used as the reference oscillator. As a result, the phase noise of the PLL circuit is mainly generated by the phase noise due to the phase comparator.

A technology used to reduce the phase noise of a phase comparator is proposed by Patent Document 1 (U.S. Pat. No. 6,509,800 (Column 7, lines 59 to 62, column 11, lines 56 to 60, and FIG. 4)). Namely, there are provided multiple pairs of a frequency divider which divides an output from a voltage controlled oscillator (VCO) and a phase comparator which compares the phase of an output from the frequency divider and the phase of a reference signal. Noise components of the multiple phase comparators then are cancelled out mutually by summing the outputs from the multiple phase comparators. There can thus be reduced phase noises of the phase comparators.

However, according to the technology described above, it is necessary to employ the multiple frequency dividers as many as the number of the phase comparators. As a result, a circuit scale, a cost, and an electrical power consumption increase accordingly.

An object of the present invention is to provide a simple configuration used to reduce the phase noise of a phase comparator in a PLL circuit.

### DISCLOSURE OF THE INVENTION

According to the present invention as described in claim 1, a signal processing apparatus includes: a voltage controlled oscillating unit that controls a frequency of an output signal according to a voltage of an input signal; an in-loop frequency dividing unit that divides the frequency of the output signal by M (M is an integer equal to or larger than two), and outputs M of output frequency divided signals; an in-loop phase shifting unit that shifts the phase of the output frequency divided signals so that the phases thereof are different from each other by 360 degrees/M; a reference frequency dividing unit that divides a frequency of a reference signal by M, and outputs M of reference frequency divided signals; a reference phase shifting unit that shifts the phase of the reference frequency divided signals so that the phases thereof are different from each other by 360 degrees/M; a plurality of phase comparing units that output signals corresponding to phase difference among the respective output frequency divided signals different in phase by 360 degrees/M, and the respective reference frequency divided signals different in phase by 360 degrees/M; a summing unit that sums the outputs from the phase comparing unit; and a low-pass filter that passes a low frequency component of an output from the summing unit, and supplies the voltage controlled oscillating unit with the low frequency component.

According to the present invention configured as described above, a voltage controlled oscillating unit controls a frequency of an output signal according to a voltage of an input signal. An in-loop frequency dividing unit divides the frequency of the output signal by M (M is an integer equal to or larger than two), and outputs M of output frequency divided signals. An in-loop phase shifting unit shifts the phase of the output frequency divided signals so that the phases thereof are different from each other by 360 degrees/M. A reference frequency dividing unit divides a frequency of a reference signal by M, and outputs M of reference frequency divided signals. A reference phase shifting unit shifts the phase of the reference frequency divided signals so that the phases thereof are different from each other by 360 degrees/M. A plurality of phase comparing units output signals corresponding to phase difference among the respective output frequency divided signals different in phase by 360 degrees/M, and the respective reference frequency divided signals different in phase by 360 degrees/M. A summing unit sums the outputs from the phase comparing unit. A low-pass filter passes a low frequency component of an output from the summing unit, and supplies the voltage controlled oscillating unit with the low frequency component.

The present invention as described in claim 2, is the signal processing apparatus according to claim 1, wherein M is obtained by raising two to an integer power.

### BRIEF DESCRIPTION OF THE DRAWINGS

FIG. 1 is a block diagram showing a configuration of a PLL circuit 1 according an embodiment of the present invention; and

FIG. 2 is a block diagram showing a configuration of a PLL circuit 1 according a variation of the embodiment of the present invention.

### BEST MODE FOR CARRYING OUT THE INVENTION

A description will now be given of an embodiment of the present invention with reference to drawings.

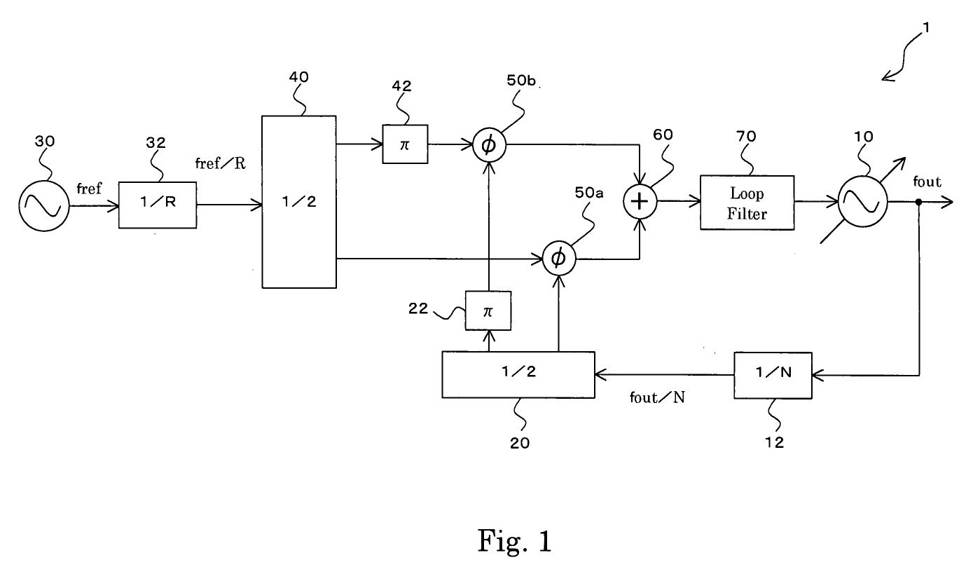

FIG. 1 is a block diagram showing a configuration of a PLL circuit 1 according the embodiment of the present invention. The PLL circuit 1 is provided with a voltage controlled oscillator (VCO) 10, a frequency divider 12, an in-loop frequency divider 20, an in-loop phase shifter part 22, a reference signal oscillator 30, a frequency divider 32, a reference frequency divider 40, a reference phase shifter part 42, phase comparators 50a and 50b, an adder (summing means) 60, and a loop filter 70.

The voltage controlled oscillator (VCO) 10 controls a frequency fₒᵤₜ of an output signal according to a voltage of an input signal.

The frequency divider 12 divides the frequency of the output signal by N. Note that N is an integer equal to or larger than 2. A fractional frequency divider may be added to the frequency divider 12.

The in-loop frequency divider 20 receives the output signal via the frequency divider 12, divides the frequency thereof by 2, and outputs two output frequency divided signals.

The in-loop phase shifter part 22 sets the two output frequency divided signals such that they are different from each other in phase by 360 degrees/2=180 degrees. For example, as shown in FIG. 1, the phase of one of the two output frequency divided signals is shifted by 180 degrees.

The reference signal oscillator 30 outputs a reference signal with a predetermined frequency of f_{ref}.

The frequency divider 32 divides the frequency of the reference signal by R. Note that R is an integer equal to or larger than 2. A fractional frequency divider may be added to the frequency divider 32.

The reference frequency divider 40 receives the reference signal via the frequency divider 32, divides the frequency thereof by 2, and outputs two reference frequency divided signals.

The reference phase shifter part 42 sets the two reference frequency divided signals such that they are different from each other in phase by 360 degrees/2=180 degrees. For example, as shown in FIG. 1, the phase of one of the two reference frequency divided signals is shifted by 180 degrees.

The phase comparators 50a and 50b output signals corresponding to respective phase differences between the output frequency divided signals different in phase by 180 degrees and the reference frequency divided signals different in phase by 180 degrees. Namely, the phase comparator 50a outputs a signal corresponding to the phase difference between the output frequency divided signal output from the in-loop frequency divider 20 and the reference frequency divided signal output from the reference frequency divider 40. The phase comparator 50b outputs a signal corresponding to the phase difference between the output frequency divided signal output from the in-loop frequency divider 20 and then phase shifted by 180 degrees by the in-loop phase shifter part 22, and the reference frequency divided signal output from the reference frequency divider 40 and then phase shifted by 180 degrees by the reference phase shifter part 42.

The adder (summing means) 60 outputs a sum of an output from the phase comparator 50a and an output from the phase comparator 50b.

The loop filter 70 passes low frequency components of the output from the adder 60, and supplies the voltage controlled oscillator 10 with the low frequency components.

A description will now be given of an operation of the embodiment of the present invention.

The voltage controlled oscillator 10 outputs the output signal with the frequency of fₒᵤₜ. The output signal is frequency divided by the frequency divider 12 by N, becomes the signal with the frequency of fₒᵤₜ/N, and is supplied to the in-loop frequency divider 20. The in-loop frequency divider 20 divides the frequency of the output signal which has become fₒᵤₜ/N by 2, and outputs the two output frequency divided signals. The one of the output frequency divided signals is directly supplied to the phase comparator 50a. The other of the output frequency divided signals is phase shifted by the in-loop phase shifter part 22 by 180 degrees, and is supplied to the phase comparator 50b.

Moreover, the reference signal oscillator 30 outputs the reference signal with the predetermined frequency of f_{ref}. The output signal is frequency divided by the frequency divider 32 by R, becomes the signal with the frequency of f_{ref}/R, and is supplied to the reference frequency divider 40. The reference frequency divider 40 divides the frequency of the reference signal which has become f_{ref}/R by 2, and outputs the two reference frequency divided signals. The one of the reference frequency divided signals is directly supplied to the phase comparator 50a. The other of the reference frequency divided signals is phase shifted by the reference phase shifter part 42 by 180 degrees, and is supplied to the phase comparator 50b.

The phase comparators 50a and 50b respectively output the signal corresponding to the phase difference between the input signals. These outputs are summed by the adder 60. The low frequency components of the output from the adder 60 pass the loop filter 70, and are supplied to the voltage controlled oscillator 10.

According to the embodiment of the present invention, a feedback loop is configured as described above, and there is thus provided fₒᵤₜ=f_{ref}×2N/2R=f_{ref}×N/R. It is possible to set fₒᵤₜ to a desired frequency by properly setting N and R.

On this occasion, a term of a phase noise corresponding to f_{ref} within a loop bandwidth is represented as 10 log(f_{ref}/2R) due to the presence of the reference frequency divider 40. Moreover, a phase noise increased twice by the in-loop frequency divider 20 is cancelled by employing the two phase comparators (phase comparators 50a and 50b), resulting in the phase noise being one second. On the other hand, an ordinary PLL circuit does not include the reference frequency divider 40, the in-loop frequency divider 20, and the phase comparator 50b, and the term of the phase noise corresponding to f_{ref} within the loop bandwidth is thus represented as 10 log (f_{ref}/R). As a result, the presence of the reference frequency divider 40, the in-loop frequency divider 20, and the phase comparator 50b increases the phase noise by 10 log(f_{ref}/2R)−10 log(f_{ref}/R)=10 log(½)=−3 [dB]. Namely, the phase noise is reduced by 3 [dB].

According to the embodiment of the present invention, there is provided an advantage that although the phase noise is reduced in this way, there is only necessary the one frequency divider 12. Compared with a case where the technology according to Patent Document 1 referenced as prior art is applied to the embodiment of the present invention, and there is thus required two of the frequency dividers 12, which corresponds to the number of the phase comparators 50a and 50b, there are brought about reductions of a circuit scale, a cost, and a power consumption.

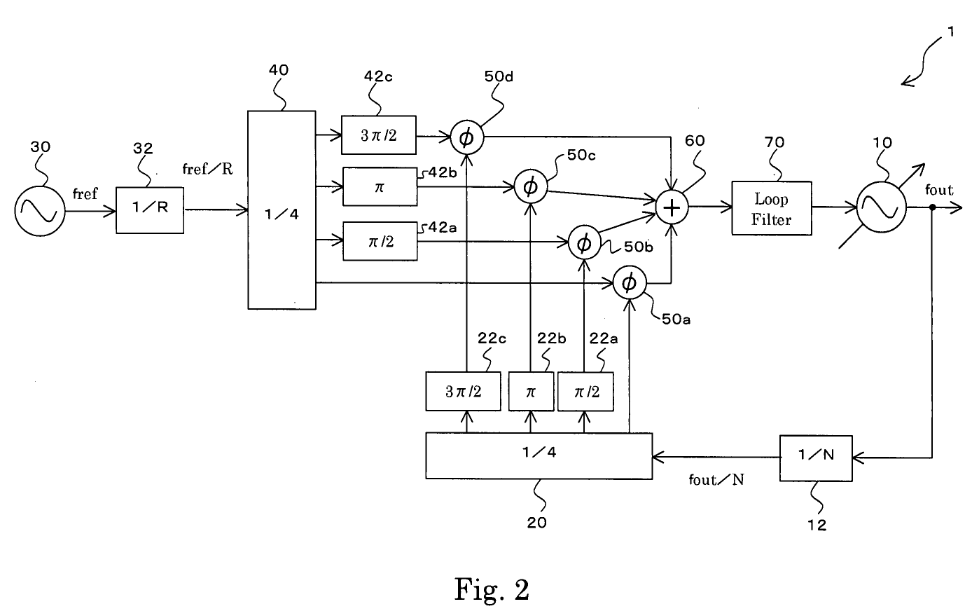

Note that a ½ frequency divider is used as the reference frequency divider 40 according to the embodiment of the present invention. However, it is possible to use a 1/M frequency divider (M is an integer equal to or more than two) as the reference frequency divider 40. For example, there may be provided a specification M=2ⁿ (n is an integer equal to or more than two). FIG. 2 shows a configuration of the PLL circuit 1 where M=2²=4.

As FIG. 2 shows, a ¼ frequency divider may be used as the reference frequency divider 40. In this case, a ¼ frequency divider is used also as the in-loop frequency divider 20. The reference frequency divider 40 outputs four reference frequency divided signals, and the in-loop frequency divider 20 also outputs four output frequency divided signals. The four reference frequency divided signals are set such that they are different from each other in phase by 360 degrees/4=90 degrees by reference phase shifter parts 42a, 42b, and 42c. The four output frequency divided signals are set such that they are different from each other in phase by 360 degrees/4=90 degrees by in-loop phase shifter parts 22a, 22b, and 22c. Phase comparators 50a, 50b, 50c, and 50d output signals corresponding to respective phase differences among the four reference frequency divided signals and the four output frequency divided signals, and the adder 60 sums the outputs.

In the example shown in FIG. 2, the term of the phase noise corresponding to f_{ref} in the loop bandwidth is represented as 10 log(f_{ref}/4R) due to the presence of the reference frequency divider 40. Moreover, a phase noise increased four times by the in-loop frequency divider 20 is cancelled by employing the four phase comparators (phase comparators 50a, 50b, 50c, and 50d), resulting in the phase noise being one fourth. On the other hand, an ordinary PLL circuit does not include the reference frequency divider 40, the in-loop frequency divider 20, and the phase comparators 50b, 50c, and 50d, and the term of the phase noise corresponding to f_{ref} within the loop bandwidth is thus represented as 10 log (f_{ref}/R). As a result, the presence of the reference frequency divider 40, the in-loop frequency divider 20, and the phase comparators 50b, 50c, and 50d increases the phase noise by 10 log(f_{ref}/4R)−10 log(f_{ref}/R)=10 log(¼)=−6 [dB]. Namely, the phase noise is reduced by 6 [dB]. In this way, the phase noise is reduced by 10 log M [dB].

Moreover, there is provided an advantage that although the phase noise is reduced in this way, there is only necessary the one frequency divider 12. Compared with a case where the technology according to Patent Document 1 referenced as prior art is applied to the variation of the embodiment of the present invention, and there is thus required four of the frequency dividers 12, which corresponds to the number of the phase comparators 50a, 50b, 50c, and 50d, there are brought about reductions of the circuit scale, the cost, and the power consumption.

1. A signal processing apparatus, comprising:
a voltage controlled oscillating means that controls a frequency of an output signal according to a voltage of an input signal;
an in-loop frequency dividing means that divides the frequency of the output signal by M (where M is an integer at least equal to two), and outputs M of output frequency divided signals;
an in-loop phase shirting means that shifts a phase of the output frequency divided signals so that phases thereof are different from each other by 360 degrees/M;
a reference frequency dividing means that divides a frequency of a reference signal by M, and outputs M reference frequency divided signals;
a reference phase shifting means that shifts a phase of the reference frequency divided signals so that phases thereof are different from each other by 360 degrees/M;
a plurality of phase comparing means that output signals corresponding to a phase difference among respective output frequency divided signals different in phase by 360 degrees/M, and respective reference frequency divided signals different in phase by 360 degrees/M;
a summing means that sums the outputs from the plurality of phase comparing means; and
a low-pass filter that passes a low frequency component of an output from said summing means, and supplies said voltage controlled oscillating means with the low frequency component.

2. The signal processing apparatus according to claim 1, wherein M is obtained by raising two to an integer power.

3. A signal processing apparatus, comprising:
a voltage controlled oscillator that controls a frequency of an output signal according to a voltage of an input signal;
an in-loop frequency divider that divides the frequency of the output signal by M (where M is an integer at least equal to two), and outputs M output frequency divided signals;
an in-loop phase shifter that shifts a phase of the output frequency divided signals so that phases thereof are different from each other by 360 degrees/M;
a reference frequency divider that divides a frequency of a reference signal by M, and outputs M reference frequency divided signals;
a reference phase shifter that shifts a phase of the reference frequency divided signals so that phases thereof are different from each other by 360 degrees/M;
a plurality of phase comparators that output signals corresponding to a phase difference among respective output frequency divided signals different in phase by 360 degrees/M, and respective reference frequency divided signals different in phase by 360 degrees/M;
an adder that sums outputs from the plurality of phase comparators; and
a low-pass filter that passes a low frequency component of an output from said summer, and supplies said voltage controlled oscillator with the low frequency component.

4. The signal processing apparatus of claim 1, wherein M is obtained by raising two to an integer power.
